(19) United States
(12) Patent Application Publication
(10) Pub. No.: US 2022/0135836 A1
(43) Pub. Date: May 5, 2022

(54) POLYIMIDE FILM FOR FLEXIBLE METAL CLAD LAMINATE AND FLEXIBLE METAL CLAD LAMINATE COMPRISING SAME

(71) Applicant: NEXFLEX CO.,LTD., Chungcheongbuk-do (KR)

(72) Inventors: Dae Nyoun KIM, Daejeon (KR); Yun Jeong JO, Daejeon (KR); Ra Mi LEE, Daejeon (KR)

(73) Assignee: NEXFLEX CO.,LTD., Chungcheongbuk-do (KR)

(21) Appl. No.: 17/452,162

(22) Filed: Oct. 25, 2021

(30) Foreign Application Priority Data
Nov. 5, 2020 (KR) 10-2020-0146729

(51) Int. Cl. C09D 179/08; C08G 73/10; H05K 1/03; H05K 1/05

(52) U.S. Cl. CPC C09D 179/08; C08G 73/1082; C08G 73/1053; H05K 2201/0355; H05K 1/0346; H05K 1/056; H05K 2201/0154; C08G 73/1032

(57) ABSTRACT

The present disclosure relates to a polyimide film for a flexible metal clad laminate and a flexible metal clad laminate including the same, and an aspect of the present disclosure is to provide a polyimide film for a flexible metal clad laminate, which is derived from a polyimide precursor composition including an acid dianhydride and a diamine, in which the acid dianhydride includes 70% by mol or more of pyromellitic dianhydride (PMDA), and the diamine includes m-tolidine and dimer diamine.

### CROSS-REFERENCE TO RELATED APPLICATION

This application claims the benefit of Korean Patent Application No. 10-2020-0146729 filed on Nov. 5, 2020, in the Korean Intellectual Property Office, the entire disclosure of which is incorporated herein by reference for all purposes.

### BACKGROUND

### 1. Field of the Invention

One or more example embodiments relate to a polyimide film for a flexible metal clad laminate and a flexible metal clad laminate including the same.

### 2. Description of the Related Art

A flexible printed circuit board (FPCB) is a PCB manufactured to be used when a flexible and thin substrate of the circuit board is required. With the recent trend of miniaturization, high speed, and various functions of electronic devices being combined, high-speed transmission, weight reduction, thinning, and miniaturization are progressing day by day, and technology development for FPCB materials corresponding to this is required.

A flexible metal clad laminate (FMCL) is a basic raw material for FPCB products and consists of a conductive metal foil and an insulating layer. Typically, a flexible copper clad laminate (FCCL) in which copper foil and polyimide are laminated is being used.

As the signal transmission speed of the electronic devices is rapidly increasing, it has been necessary to develop an insulator with lower dielectric constant and dielectric loss than conventional insulators. In this regard, various studies are being conducted to improve dielectric properties of an insulating resin constituting the flexible metal clad laminate.

For example, a composite material in which a polyimide resin constituting an insulating layer of the flexible metal clad laminate is mixed with a fluorine-based resin having excellent dielectric properties, or silica surface-treated to have hydrophobicity is used has been developed.

However, in the case of such a material, there are problems in that the interfacial bonding force is low due to a difference in organic and inorganic characteristics, it is difficult to control the dispersibility due to a difference in specific gravity, and it is difficult to secure the dimensions due to a difference in the coefficient of thermal expansion with a metal foil.

Therefore, it is necessary to develop a technology capable of improving dielectric properties of pure polyimide.

The above-mentioned background art has been possessed or acquired by the inventor in the process of deriving the disclosure content of the present application, and it cannot necessarily be said to be a known technology disclosed to the general public prior to the present application.

### SUMMARY

In order to solve the aforementioned problems, example embodiments provide a polyimide precursor composition for a flexible metal clad laminate, which realizes low hygroscopicity and low dielectric loss of polyimide that is an insulating resin and is capable of securing dimensional stability during manufacturing by reducing a difference in coefficient of thermal expansion with the metal foil, and a polyimide film for the flexible metal clad laminate derived therefrom.

However, the problems to be solved by the present disclosure are not limited to those mentioned above, and other problems not mentioned will be clearly understood by those skilled in the art from the following description.

According to an aspect, there is provided a polyimide film for a flexible metal clad laminate, which is derived from a polyimide precursor composition including an acid dianhydride and a diamine, in which the acid dianhydride includes 70% by mol or more of pyromellitic dianhydride (PMDA), and the diamine includes m-tolidine and dimer diamine.

According to an example embodiment, the acid dianhydride may further include one or more of 3,3′,4,4′-biphenyltetracarboxylic dianhydride (s-BPDA), 2,3,3′,4′-biphenyltetracarboxylic dianhydride (a-BPDA), 4,4′-oxydiphthalic dianhydride (ODPA), diphenylsulfone-3,4,3′,4′-tetracarboxylic dianhydride (DSDA), bis(3,4-dicarboxyphenyl)sulfide dianhydride, 2,2-bis(3,4-dicarboxyphenyl)-1,1,1,3,3,3-hexafluoropropane dianhydride, 2,3,3′,4′-benzophenonetetracarboxylic dianhydride, 3,3′,4,4′-benzophenonetetracarboxylic dianhydride (BTDA), bis(3,4-dicarboxyphenyl)methane dianhydride, 2,2-bis(3,4-dicarboxyphenyl)propane dianhydride, p-phenylenebis(trimellitic acid monoester anhydride), p-biphenylenebis(trimellitic acid monoester anhydride), m-terphenyl-3,4,3′,4′-tetracarboxylic dianhydride, p-terphenyl-3,4,3′,4′-tetracarboxylic dianhydride, 1,3-bis(3,4-dicarboxyphenoxy)benzene dianhydride, 1,4-bis(3,4-dicarboxyphenoxy)benzene dianhydride, 1,4-bis(3,4-dicarboxyphenoxy)biphenyl dianhydride, 2,2-bis[(3,4-dicarboxyphenoxy)phenyl]propane dianhydride (BPADA), 2,3,6,7-naphthalenetetracarboxylic acid dianhydride, 1,4,5,8-naphthalenetetracarboxylic dianhydride, and 4,4′-(2,2-hexafluoroisopropylidene)diphthalic acid dianhydride.

According to an example embodiment, the m-tolidine and the dimer diamine may have a molar ratio of 1:0.01 to 1:0.2.

According to an example embodiment, the diamine may further include one or more of 2,2-bis[4-(4-aminophenoxy)phenyl]propane, 1,3-bis(4-aminophenoxy)benzene, p-phenylenediamine (p-PDA), and 4,4′-diaminodiphenyl ether (ODA).

According to an example embodiment, the dimer diamine may include a hydrophobic aliphatic chain.

According to an example embodiment, the acid dianhydride and the diamine may have a molar ratio of 1:0.8 to 1:1.1.

According to an example embodiment, the dielectric loss (Df) may be 0.005 or less after moisture absorption (23° C./50% RH) at 10 GHz.

According to an example embodiment, the moisture absorption rate may be 1% or less, and the coefficient of thermal expansion may be 25 ppm/K or less.

According to an example embodiment, the metal foil may be a copper foil.

According to an example embodiment, the polyimide precursor composition may have a solid content of 5 to 20% by weight.

According to another aspect, there is provided a flexible metal clad laminate including: the polyimide film for the flexible metal clad laminate; and an electroconductive metal foil, in which the polyimide film is formed on the metal foil.

According to still another aspect, there is provided an electronic component including the flexible metal clad laminate and transmitting a signal at a high frequency of 10 GHz.

Additional aspects of example embodiments will be set forth in part in the description which follows and, in part, will be apparent from the description, or may be learned by practice of the disclosure.

According to example embodiments, a polyimide film for a flexible metal clad laminate has effects of having low moisture absorption rate and low dielectric loss and enabling dimensional stability to be secured when manufacturing the flexible metal clad laminate by minimizing a difference in coefficient of thermal expansion with the metal foil.

In particular, the polyimide film for the flexible metal clad laminate has an advantage that it can be applied as a material for electronic components transmitting a signal in the high-frequency region by exhibiting low moisture absorption rate and low dielectric loss in a high-frequency region of 10 GHz or higher.

Further, according to example embodiments, the flexible metal clad laminate has effects of improving moisture absorption rate and dielectric loss characteristics without reducing interfacial bonding force and surface flatness by including an aliphatic chain-containing polyimide as an insulating layer.

### DETAILED DESCRIPTION

Hereinafter, embodiments will be described in detail. However, since various changes may be made to the embodiments, the scope of rights of the patent application is not restricted or limited by these embodiments. It should be understood that all modifications, equivalents and substitutes for the embodiments are included in the scope of the rights.

The terms used in the embodiments are used for the purpose of description only and should not be construed as an intention to limit the present disclosure. The singular expression includes the plural expression unless the context clearly dictates otherwise. In the present specification, it should be understood that a term such as “comprise”, “have”, or the like is intended to designate that a feature, a number, a step, an operation, a component, a part, or a combination thereof described in the specification exists, but it does not preclude the possibility of existence or addition of one or more other features, numbers, steps, operations, components, parts, or combinations thereof.

Unless defined otherwise, all terms used herein, including technical or scientific terms, have the same meaning as those commonly understood by one of ordinary skill in the art to which the embodiments belong. Terms such as those defined in a commonly used dictionary should be interpreted as having a meaning consistent with the meaning in the context of the related art and should not be interpreted in an ideal or excessively formal meaning unless explicitly defined in the present application.

Further, in the description of the embodiments, if it is determined that a detailed description of a related known technology may unnecessarily obscure the gist of the embodiments, the detailed description thereof will be omitted.

Further, in describing constituent elements of the embodiments, terms such as first, second, A, B, (a), (b), etc. may be used. These terms are only for distinguishing the constituent elements from other constituent elements, and essences, orders, sequences, or the like of the corresponding constituent elements are not limited by the terms. When it is described that a constituent element is “linked”, “coupled” or “connected” to another constituent element, the constituent element may be directly linked or connected to the other constituent element, but it should be understood that another constituent element may also be “linked”, “coupled” or “connected” between the respective constituent elements.

Constituent elements included in any one embodiment and constituent elements including a common function will be described using the same names in other embodiments. Unless otherwise stated, descriptions described in any one embodiment may also be applied to other embodiments, and detailed descriptions will be omitted within the overlapping range.

According to an aspect, there is provided a polyimide film for a flexible metal clad laminate, which is derived from a polyimide precursor composition including an acid dianhydride and a diamine, in which the acid dianhydride includes 70% by mol or more of pyromellitic dianhydride (PMDA), and the diamine includes m-tolidine and dimer diamine.

The polyimide film for the flexible metal clad laminate according to the present disclosure is derived from a polyimide precursor composition using an acid dianhydride including pyromellitic dianhydride (PMDA) and a diamine including m-tolidine and dimer diamine so that it has effects of simultaneously improving dielectric loss, moisture absorption rate, and coefficient of thermal expansion and has characteristics suitable for application as an FPCB material for high-speed transmission.

Further, since it includes only pure polyimide that does not include a separate fluorine-based resin or inorganic material for improving dielectric properties, the polyimide film for the flexible metal clad laminate according to the present disclosure may solve problems such as a decrease in the interfacial bonding force due to differences in organic and inorganic characteristics, rupture of the insulating layer due to repeated bending, difficulty in controlling the dispersibility due to specific gravity difference, difficulty in securing the dimensions due to the difference in coefficient of thermal expansion with the metal foil, and difficulty in controlling the thickness according to inorganic particles.

According to an example embodiment, the acid dianhydride may include pyromellitic dianhydride (PMDA) in an amount of 70% by mol or more, preferably 75% by mol or more.

That is, the acid dianhydride may include pyromellitic dianhydride (PMDA) in an amount of 70 to 100% by mol, preferably 75 to 100% by mol.

If the acid dianhydride includes less than 75% by mol of pyromellitic dianhydride, the dimensional stability may be lowered due to an increase in the coefficient of thermal expansion, and heat resistance problems may occur in the drilling process during PCB manufacturing due to low Tg.

The pyromellitic dianhydride may improve flatness, elasticity, and durability of the film when forming the polyimide film.

According to an example embodiment, the acid dianhydride may further include one or more of 3,3′,4,4′-biphenyltetracarboxylic dianhydride (s-BPDA), 2,3,3′,4′-biphenyltetracarboxylic dianhydride (a-BPDA), 4,4′-oxydiphthalic dianhydride (ODPA), diphenylsulfone-3,4,3′,4′-tetracarboxylic dianhydride (DSDA), bis(3,4-dicarboxyphenyl)sulfide dianhydride, 2,2-bis(3,4-dicarboxyphenyl)-1,1,1,3,3,3-hexafluoropropane dianhydride, 2,3,3′,4′-benzophenonetetracarboxylic dianhydride, 3,3′,4,4′-benzophenonetetracarboxylic dianhydride (BTDA), bis(3,4-dicarboxyphenyl)methane dianhydride, 2,2-bis(3,4-dicarboxyphenyl)propane dianhydride, p-phenylenebis(trimellitic acid monoester anhydride), p-biphenylenebis(trimellitic acid monoester anhydride), m-terphenyl-3,4,3′,4′-tetracarboxylic dianhydride, p-terphenyl-3,4,3′,4′-tetracarboxylic dianhydride, 1,3-bis(3,4-dicarboxyphenoxy)benzene dianhydride, 1,4-bis(3,4-dicarboxyphenoxy)benzene dianhydride, 1,4-bis(3,4-dicarboxyphenoxy)biphenyl dianhydride, 2,2-bis[(3,4-dicarboxyphenoxy)phenyl]propane dianhydride (BPADA), 2,3,6,7-naphthalenetetracarboxylic acid dianhydride, 1,4,5,8-naphthalenetetracarboxylic dianhydride, and 4,4′-(2,2-hexafluoroisopropylidene)diphthalic acid dianhydride.

The acid dianhydride may impart other properties to the polyimide film by including one or more acid dianhydride components other than pyromellitic dianhydride.

According to an example embodiment, the acid dianhydride may further include biphenyltetracarboxylic dianhydride (BPDA), and BPDA may improve low hygroscopicity and flexibility of the polyimide film.

According to an example embodiment, the acid dianhydride may include an acid dianhydride component other than pyromellitic dianhydride in an amount of 30% by mol or less, preferably 25% by mol or less.

That is, the acid dianhydride may include an acid dianhydride component other than pyromellitic dianhydride in an amount of 1 to 30% by mol, preferably 1 to 25% by mol.

If the acid dianhydride component other than pyromellitic dianhydride is out of the above content range, the effect of simultaneously improving the dielectric loss, moisture absorption rate, and coefficient of thermal expansion of a formed polyimide film may not appear.

In the polyimide film according to the present disclosure, the polyimide precursor composition includes m-tolidine and dimer diamine.

According to an example embodiment, the m-tolidine and the dimer diamine may have a molar ratio of 1:0.01 to 1:0.2.

Preferably, the m-tolidine and the dimer diamine may have a molar ratio of 1:0.03 to 1:0.2, more preferably 1:0.05 to 1:0.2, and even more preferably 1:0.05 to 1:0.18.

According to an example embodiment, the m-tolidine and the dimer diamine may have a molar ratio of 85:15 to 95:5.

The molar ratio of the m-tolidine and the dimer diamine may act as a key factor for simultaneously improving the dielectric loss, moisture absorption rate, and coefficient of thermal expansion of the formed polyimide film.

Further, when the dimer diamine has a molar content less than the above range based on the molar content of the m-tolidine, low moisture absorption properties and low dielectric loss properties may be deteriorated, and when it has a molar content exceeding the above range, mechanical properties or heat resistance of the polyimide film may be deteriorated.

According to an example embodiment, the diamine may further include one or more of 2,2-bis[4-(4-aminophenoxy)phenyl]propane, 1,3-bis(4-aminophenoxy)benzene, p-phenylenediamine (p-PDA), and 4,4′-diaminodiphenyl ether (ODA).

According to an example embodiment, the dimer diamine may include a hydrophobic aliphatic chain.

In order to implement a low dielectric loss, it is advantageous to have low moisture absorption properties. However, since polyimide is generally composed of an imide group having strong polarity in the main chain, it has high hygroscopicity.

In order to solve this, the polyimide film according to the present disclosure has characteristics of lowering hygroscopicity and realizing a low dielectric loss by giving hydrophobicity to polyimide using an aliphatic monomer having hydrophobicity, that is, dimer diamine having a hydrophobic aliphatic chain.

For example, Priamine™ 1074, Priamine™ 1071, Priamine™ 1073, Priamine™ 1075, or a mixture thereof may be used as the dimer diamine.

According to an example embodiment, the acid dianhydride and the diamine may have a molar ratio of 1:0.8 to 1:1.1.

Preferably, the acid dianhydride and the diamine may have a molar ratio of 1:0.9 to 1:1.0.

In the polyimide film according to the present disclosure, the type and molar ratio of the acid dianhydride and the diamine contained in the polyimide precursor composition, the molar ratio between the acid dianhydride components, and the molar ratio between the diamine components may be key action factors in realizing low moisture absorption rate, low dielectric loss, and the minimization of a difference in the coefficient of thermal expansion with the metal foil.

According to an example embodiment, the polyimide film according to the present disclosure may have a thickness of 12 to 100 μm.

According to an example embodiment, the dielectric loss (Df) may be 0.005 or less after moisture absorption (23° C./50% RH) at 10 GHz.

The dielectric loss (Df) or dielectric loss factor refers to a force dissipated by a dielectric (or insulator) when the friction of molecules interferes with the molecular motion caused by an alternating electric field.

A value of the dielectric loss factor is commonly used as an index indicating the easiness of loss of electric charge (dielectric loss), and the higher the dielectric loss factor, the easier it may become to lose the electric charge, whereas the lower the dielectric loss factor, the more difficult it may become to lose the electric charge. That is, the dielectric loss factor is a measure of power loss, and the lower the dielectric loss factor, the faster the communication speed may be maintained while the signal transmission delay due to the power loss is being alleviated.

The polyimide film according to the present disclosure has low dielectric loss properties by exhibiting a dielectric loss (Df) of 0.005 or less after constant temperature and moisture absorption in a high frequency region of 10 GHz.

In particular, considering that technologies to date for improving dielectric properties are mainly focused on a technology related to low dielectric constant of the insulator, the polyimide film according to the present disclosure is meaningful in that it presents a technology capable of realizing low dielectric loss properties.

According to an example embodiment, the moisture absorption (23° C./50% RH) may be performed for 24 hours.

According to an example embodiment, the dielectric loss (Df) may be 0.035 or less, 0.0033 or less, 0.0025 or less, or 0.0022 or less after moisture absorption (23° C./50% RH) at 10 GHz.

According to an example embodiment, the moisture absorption rate may be 1% or less, and the coefficient of thermal expansion may be 25 ppm/K or less.

The moisture absorption rate is a ratio indicating the amount of moisture absorbed by a material, and it is generally known that when the moisture absorption rate is high, the dielectric constant and dielectric loss factor increase.

In general, it is known that when water is in a solid state, the dielectric constant is 100 or more, when water is in a liquid state, it is about 80, and when water is water vapor of a gas state, it is 1.0059.

Water, which exists in a water vapor state outside the polyimide film, does not substantially affect the dielectric constant and dielectric loss factor of the polyimide film. However, in a state that water vapor or the like is absorbed into the polyimide film, water exists in a liquid state. In this case, the dielectric constant and dielectric loss factor of the polyimide film may rapidly increase.

That is, the dielectric constant and dielectric loss factor of the polyimide film may change rapidly even with a small amount of moisture absorption only. Therefore, lowering the moisture absorption rate may be seen as a very important factor for the polyimide film as an insulating film.

The polyimide film according to the present disclosure not only exhibits a low moisture absorption rate of 1% or less, but also secures a coefficient of thermal expansion of 25 ppm/K or less so that it may improve dimensional stability by reducing the difference in the coefficient of thermal expansion with the metal foil when manufacturing a flexible metal clad laminate.

As a specific example, since the polyimide film according to the present disclosure may secure a coefficient of thermal expansion of 25 ppm/K or less in a temperature range of 100 to 200° C., and the copper foil may have a coefficient of thermal expansion of around 17 ppm/K in the same temperature range, dimensional stability may be improved by reducing the difference in the coefficient of thermal expansion with the copper foil when manufacturing a flexible copper clad laminate.

According to an example embodiment, the polyimide film may secure a coefficient of thermal expansion of 25 ppm/K or less, 23 ppm/K or less, 15 ppm/K or less, or 6 ppm/K or less while exhibiting a low moisture absorption rate of 1% or less.

According to an example embodiment, the polyimide film may exhibit a low moisture absorption rate of 0.85% or less.

In the flexible metal clad laminate to which the polyimide film according to the present disclosure is applied, the metal foil is not limited as long as it is commonly used in the relevant field.

For example, the metal foil may be a metal foil made of copper, iron, stainless steel, nickel, aluminum, or an alloy of each thereof.

The metal foil may have an anti-rust layer, a heat-resistant layer, or an adhesive layer applied to its surface.

According to an example embodiment, the metal foil may be a copper foil. That is, the polyimide film according to the present disclosure may be for the flexible copper clad laminate.

In particular, the polyimide film according to the present disclosure has an effect of enabling dimensional stability to be secured when manufacturing the flexible copper clad laminate since it does not have a large difference in the coefficient of thermal expansion with the copper foil.

According to an example embodiment, the polyimide precursor composition may include an organic solvent.

One or more of dimethylacetamide (DMAc), N-methyl-2-pyrrolidone (NMP), dimethylformamide (DMF), dimethyl sulfoxide (DMSO), acetone, diethyl acetate, and m-cresol may be used as the organic solvent.

According to an example embodiment, the organic solvent may be dimethylacetamide (DMAc).

According to an example embodiment, the polyimide precursor composition may have a solid content of 5 to 20% by weight.

Preferably, the polyimide precursor composition may have a solid content of 10 to 15% by weight.

The solid content range may be for securing a molecular weight and viscosity suitable for forming the polyimide film.

The polyimide film according to the present disclosure may be obtained by performing imidization of a polyimide precursor composition including an acid dianhydride and a diamine.

As the imidization, a known method may be used, and a thermal imidization method, a chemical imidization method, or a complex imidization method using a combination of the thermal imidization method and the chemical imidization method may be used.

According to an example embodiment, the polyimide film may be obtained by performing imidization of the polyimide precursor composition including the acid dianhydride and the diamine by the thermal imidization method.

According to an example embodiment, the imidization by the thermal imidization method may be carried out through processes of coating the polyimide precursor composition on a metal foil, performing a primary heat treatment at a temperature of 120 to 160° C. for 10 to 20 minutes, and then performing a secondary heat treatment of raising the temperature from room temperature to a temperature of 300 to 400° C. under a nitrogen atmosphere.

Another aspect of the present disclosure provides a flexible metal clad laminate including: a polyimide film for the flexible metal clad laminate; and an electroconductive metal foil.

The flexible metal clad laminate may have a form in which the electroconductive metal foil is laminated on one surface or both surfaces of the polyimide film for the flexible metal clad laminate.

Alternatively, the flexible metal clad laminate may have a form in which the polyimide film for the flexible metal clad laminate is laminated on one surface or both surfaces of the electroconductive metal foil.

Another aspect of the present disclosure provides a flexible metal clad laminate including: the polyimide film for the flexible metal clad laminate; and the electroconductive metal foil, in which the polyimide film is formed on the metal foil.

According to an example embodiment, two or more of the polyimide films for the flexible metal clad laminate may be laminated to form a plurality of layers. That is, a first polyimide layer, a second polyimide layer, and an n-th polyimide layer may be formed on the metal foil.

In the flexible metal clad laminate according to the present disclosure, the thickness of the metal foil may be determined depending on its use and function.

According to an example embodiment, the metal foil may have a thickness of 1 to 100 μm, preferably 10 to 60 μm, or 10 to 40 μm, and more preferably 10 to 20 μm.

According to an example embodiment, the flexible metal clad laminate may be a flexible copper clad laminate. The flexible copper clad laminate has an advantage suitable for being applied as an FPCB material for high-speed transmission in the 5G era.

Another aspect of the present disclosure provides an electronic component including the flexible metal clad laminate and transmitting a signal at a high frequency of 10 GHz.

For example, the electronic component may be a communication circuit for a portable terminal, a communication circuit for a computer, or a communication circuit for aerospace.

Another aspect of the present disclosure provides a method for manufacturing a film for a flexible metal clad laminate, including the steps of: coating a polyimide precursor composition on a metal foil and then performing a drying process to obtain a laminate in which a coating layer is formed; raising the temperature of the coating layer to a temperature of 300 to 400° under a nitrogen atmosphere to form a polyimide; and removing the metal foil from a laminate in which the polyimide is formed.

The polyimide precursor composition may include an acid dianhydride and a diamine, the acid dianhydride may include 70% by mol or more of pyromellitic dianhydride (PMDA), and the diamine may include m-tolidine and dimer diamine.

The polyimide precursor composition may be prepared by dissolving the diamine in an organic solvent and then adding the acid dianhydride. At this time, a polyamic acid may be formed.

The prepared polyimide precursor composition may be dried at a temperature of 120 to 160° C. for 10 to 20 minutes after being coating on the metal foil.

Thereafter, the polyamic acid is converted into polyimide by raising the temperature from room temperature to a temperature of 300 to 400° C. under a nitrogen atmosphere.

When the polyimide is formed on the metal foil, a flexible metal clad laminate in a form in which the polyimide film is laminated on the metal foil may be obtained.

At this time, when the metal foil is removed from the laminate, a film for the flexible metal clad laminate may be obtained.

In the step of forming the coating layer, the coating method is not limited, and knife coating, roll coating, die coating, curtain coating, or casting coating may be used.

Another aspect of the present disclosure provides a method for manufacturing the flexible metal clad laminate, including the steps of: coating a polyimide precursor composition on a metal foil and then performing a drying process to obtain a laminate in which a coating layer is formed; and raising the temperature of the coating layer to a temperature of 300 to 400° C. under a nitrogen atmosphere to form a polyimide resin.

Hereinafter, the present disclosure will be described in more detail by Examples and Comparative Examples.

However, the following Examples are only for exemplifying the present disclosure, and the content of the present disclosure is not limited to the following Examples.

### Examples

Amine-based m-tolidine and dimer diamine (Priamine 1075) were dissolved in a dimethylacetamide (DMAc) solvent in a nitrogen atmosphere. After sufficiently dissolving amine-based m-tolidine and dimer diamine in the dimethylacetamide (DMAc) solvent, anhydrous pyromellitic dianhydride (PMDA) was injected to prepare low-dielectric polyimide (PI) varnishes having a total solid content of 13% by weight.

Prepared polyamic acid resins were coated on 12-18 μm copper foils, and then were dried at 140° C. for 10 minutes. Thereafter, the polyamic acid resins were converted into polyimide resins by raising the temperature from room temperature to 350° C. under a nitrogen atmosphere. Finally, the copper foils were removed from copper foil/polyimide laminates to obtain PI films.

### Comparative Examples

As Comparative Examples, PI films were obtained in the same manner as in Examples by varying the content ranges of acid dianhydrides and diamines and additionally using ODA.

The types and contents (% by mol) of the respective acid dianhydrides and diamines used in Examples and Comparative Examples are shown in Table 1.

TABLE 1

| | Classification | | | | |
|---|---|---|---|---|---|
| | Acid dianhydride | | Diamine | | |
| | (% by mol) | | (% by mol) | | |
| | Pyromellitic | | m- | Dimer | |
| | anhydride | BPDA | tolidine | diamine | ODA |
| Example 1 | 100 | 0 | 95 | 5 | 0 |
| Example 2 | 100 | 0 | 90 | 10 | 0 |
| Example 3 | 100 | 0 | 87 | 13 | 0 |
| Example 4 | 100 | 0 | 85 | 15 | 0 |
| Example 5 | 75 | 25 | 95 | 5 | 0 |
| Com. Example 1 | 100 | 0 | 100 | 0 | 0 |
| Com. Example 2 | 100 | 0 | 75 | 0 | 25 |

### Experimental Example

1. Measurement of Dielectric Loss Values

Dielectric loss values were measured by resonant cavity method using Keysight's network analyzer.

After drying the polyimide films (insulating layers) of Examples and Comparative Examples above at a temperature of 120° C., moisture inside the insulating layers was removed to prepare respective specimens.

Each of the prepared specimens was stored in a 23° C./50 RH % thermo-hygrostat for 24 hours, and then dielectric loss values were measured in a hygroscopic environment.

2. Measurement of Moisture Absorption Rate Values

After pretreating each of the prepared specimens at constant temperature and humidity for 24 hours, moisture absorption rate values of the polyimide films (insulating layers) were measured by weighing the specimens before and after the pretreatment.

3. Measurement of Coefficient of Thermal Expansion (CTE) Values After raising the temperature of each of the prepared specimens from room temperature to 300° C., coefficient of thermal expansion values in a range of 100 to 200° C. were measured using Hitachi's thermomechanical analyzer (TMA).

The measured numerical values of dielectric loss, moisture absorption rate, and coefficient of thermal expansion (CTE) are shown in Table 2.

TABLE 2

| | Dielectric loss | Moisture | |
|---|---|---|---|
| | (Df@23° C./ | absorption rate | CTE |
| | 50% RH 10 GHz) | (%) | (ppm/K) |
| Example 1 | 0.0049 | 0.83 | 5.9 |
| Example 2 | 0.0035 | 0.70 | 14.7 |
| Example 3 | 0.0025 | 0.50 | 23 |
| Example 4 | 0.0022 | 0.45 | 25 |
| Example 5 | 0.0033 | 0.65 | 23 |
| Com. Example 1 | 0.0084 | 1.6 | 3.1 |
| Com. Example 2 | 0.0095 | 2.0 | 30 |

Referring to the results of Table 2 above, it can be confirmed that, in the case of all Examples, the dielectric loss values are less than 0.005, the moisture absorption rate values are 1% or less, and the coefficient of thermal expansion values are 25 ppm/K or less.

On the other hand, it can be confirmed that the numerical values of dielectric loss and moisture absorption rate are high in the case of Comparative Example 1, and the numerical values of dielectric loss, moisture absorption rate, and coefficient of thermal expansion are all very high in the case of Comparative Example 2. That is, it can be seen that when only m-tolidine is used, or m-tolidine and ODA are used as the diamine, the improvement effects of dielectric loss, moisture absorption rate, and coefficient of thermal expansion are all deteriorated, or not improved at the same time.

Therefore, it can be seen that dielectric loss, moisture absorption rate, and coefficient of thermal expansion have all been improved in the polyimide film according to the present disclosure, and in particular, it can be seen that the dielectric loss has been effectively reduced in a high-frequency (10 GHz) hygroscopic environment.

Although Examples have been described as described above, those skilled in the art may apply various technical modifications and variations based on the above description. For example, although the described techniques are performed in a different order than the described method, and/or the constituent elements such as the described system, structure, apparatus, circuit, etc. are coupled or combined in a different form than the described method, or replaced or substituted by other constituent elements or equivalents, appropriate results may be accomplished.

Therefore, other embodiments, other examples, and equivalents to the patent claim scope also belong to the scope of the claims to be described later.

What is claimed is:

1. A polyimide film for a flexible metal clad laminate, which is derived from a polyimide precursor composition comprising an acid dianhydride and a diamine,
wherein the acid dianhydride includes 70% by mol or more of pyromellitic dianhydride (PMDA), and the diamine includes m-tolidine and dimer diamine.

2. The polyimide film for the flexible metal clad laminate of claim 1, wherein the acid dianhydride further includes one or more selected from the group consisting of 3,3′,4,4′-biphenyltetracarboxylic dianhydride (s-BPDA), 2,3,3′,4′-biphenyltetracarboxylic dianhydride (a-BPDA), 4,4′-oxydiphthalic dianhydride (ODPA), diphenylsulfone-3,4,3′,4′-tetracarboxylic dianhydride (DSDA), bis(3,4-dicarboxyphenyl)sulfide dianhydride, 2,2-bis(3,4-dicarboxyphenyl)-1,1,1,3,3,3-hexafluoropropane dianhydride, 2,3,3′,4′-benzophenonetetracarboxylic dianhydride, 3,3′,4,4′-benzophenonetetracarboxylic dianhydride (BTDA), bis(3,4-dicarboxyphenyl)methane dianhydride, 2,2-bis(3,4-dicarboxyphenyl)propane dianhydride, p-phenylenebis(trimellitic acid monoester anhydride), p-biphenylenebis(trimellitic acid monoester anhydride), m-terphenyl-3,4,3′,4′-tetracarboxylic dianhydride, p-terphenyl-3,4,3′,4′-tetracarboxylic dianhydride, 1,3-bis(3,4-dicarboxyphenoxy)benzene dianhydride, 1,4-bis(3,4-dicarboxyphenoxy)benzene dianhydride, 1,4-bis(3,4-dicarboxyphenoxy)biphenyl dianhydride, 2,2-bis[(3,4-dicarboxyphenoxy)phenyl]propane dianhydride (BPADA), 2,3,6,7-naphthalenetetracarboxylic acid dianhydride, 1,4,5,8-naphthalenetetracarboxylic dianhydride, and 4,4′-(2,2-hexafluoroisopropylidene)diphthalic acid dianhydride.

3. The polyimide film for the flexible metal clad laminate of claim 1, wherein the m-tolidine and the dimer diamine have a molar ratio of 1:0.01 to 1:0.2.

4. The polyimide film for the flexible metal clad laminate of claim 1, wherein the diamine further includes one or more selected from the group consisting of 2,2-bis[4-(4-aminophenoxy)phenyl]propane, 1,3-bis(4-aminophenoxy)benzene, p-phenylenediamine (p-PDA), and 4,4′-diaminodiphenyl ether (ODA).

5. The polyimide film for the flexible metal clad laminate of claim 1, wherein the dimer diamine includes a hydrophobic aliphatic chain.

6. The polyimide film for the flexible metal clad laminate of claim 1, wherein the acid dianhydride and the diamine have a molar ratio of 1:0.8 to 1:1.1.

7. The polyimide film for the flexible metal clad laminate of claim 1, wherein the dielectric loss (Df) is 0.005 or less after moisture absorption (23° C./50% RH) at 10 GHz.

8. The polyimide film for the flexible metal clad laminate of claim 1, wherein a moisture absorption rate is 1% or less, and a coefficient of thermal expansion is 25 ppm/K or less.

9. The polyimide film for the flexible metal clad laminate of claim 1, wherein the metal foil is a copper foil.

10. The polyimide film for the flexible metal clad laminate of claim 1, wherein the polyimide precursor composition has a solid content of 5 to 20% by weight.

11. A flexible metal clad laminate comprising:
the polyimide film for the flexible metal clad laminate of claim 1; and
an electroconductive metal foil,
wherein the polyimide film is formed on the metal foil.

12. An electronic component including the flexible metal clad laminate of claim 11 and transmitting a signal at a high frequency of 10 GHz.
